(19) United States
(12) Patent Application Publication
(10) Pub. No.: US 2003/0076096 A1
(43) Pub. Date: Apr. 24, 2003

(54) Apparatus and method of increasing the sensitivity of magnetic sensors used in magnetic field transmission and detection systems

(75) Inventors: Ruan Lourens, Chandler, AZ (US); Steven Dawson, Scottsdale, AZ (US); Pieter Schieke, Phoenix, AZ (US)

Correspondence Address: BAKER BOTTS, LLP, 910 LOUISIANA, HOUSTON, TX, 77002-4995, US

(73) Assignee: MICROCHIP TECHNOLOGY INCORPORATED

(21) Appl. No.: 09/983,011

(22) Filed: Oct. 18, 2001

(51) Int. Cl. G01R 33/02

(52) U.S. Cl. 324/258

(57) ABSTRACT

The present invention is directed to an apparatus and method of increasing the sensitivity of a magnetic sensor embedded in a key fob used in passive keyless entry and identification systems. The sensitivity of the sensor is increased by magnetically coupling a pair of magnetic flux concentrators at opposite ends of the magnetic core of the sensor, which is surrounded by a helical conductive coil. Addition of the magnetic flux concentrators external to the coil effectively forces a larger window of magnetic flux through the coil than was possible without them. This increases the magnetic sensitivity of the coil as a sensor in a time varying magnetic field. In a key fob/passive keyless device this results in an increased range of operation.

### RELATED APPLICATIONS

This application is related to co-pending patent applications Ser No. ______ [attorney docket number 068354.1178/MTI-1891], entitled “Apparatus and Method of Increasing the Sensitivity of Magnetic Sensors Used in Magnetic Field Transmission and Detection Systems,” filed Oct. 18, 2001, by Ruan Lourens, Paul Forton and Michel Sonnabend, and Ser. No. ______ [attorney docket number 068354.1179/MTI-1892], entitled “Reducing Orientation Directivity and Improving Operating Distance of Magnetic Sensor Coils in a Magnetic Field,” filed Oct. 18, 2001, by Ruan Lourens, both applications are hereby incorporated by reference herein for all purposes.

### FIELD OF THE INVENTION

The present invention relates generally to inductively coupled magnetic field transmission and detection systems, such as a key fob in combination with an interrogation system, and more particularly to an apparatus and method for increasing the magnetic sensitivity of the magnetic sensor employed in such systems.

### BACKGROUND OF THE INVENTION TECHNOLOGY

The use of passive keyless entry systems in automobile, home security, and other applications has increased significantly recently. These systems have increased the convenience of entering an automobile, for example, especially when the vehicle operator's hands are full, for example, with groceries.

These systems typically comprise a base station, which is normally placed in the vehicle in automobile applications, or in the home in home applications, and one or more transponders or receivers, e.g., key fobs, which communicate with the base station. In simplest terms, the base station acts as an interrogator sending a signal, which can be identified by the transponders. The transponders respond by transmitting a response signal, which can be identified by the base station. The base station typically comprises a signal transmitting coil and a signal detection device. The transmitting coil is an inductor, which generates a time varying magnetic field, known as a carrier signal. The inductor can resonate at any number of frequencies. One such frequency is 125 kHz (kilohertz). The key fob has a signal receiving coil, which is designed to resonate at the carrier frequency. Thus, when the key fob is within the range of the signal generated by the base station, the two devices are magnetically coupled.

In the simpler configurations of these systems, the key fob operates to create a characteristic change in the magnetic field generated by the base station, which can be detected by the electronics associated with the base station. This change in the magnetic field, which is detected by the base station, is used to trigger a mode of operation for the system, which in the case of a passive keyless entry system for an automobile, for example, is to unlock the vehicle.

In more sophisticated passive keyless entry systems, the key fob transponder has a separate electrical circuit operative to output a modulated radio frequency (RF) identification signal, which can be detected by a receiving device in the base station. An example of such a device is the KEELOQ transponder evaluation kit sold by Microchip Technologies, Inc. A limitation of these types of systems is that the sensitivity of the coils in the key fob is limited. This effects the range in which the key fob can operate in communication with the base station because the field intensity, known as the flux density, of the magnetic field, which is what the sensor senses, decreases with the cube of the distance from the source, i.e., 1/d³. Existing key fob sensors have a very limited range because the magnetic coils are small, and thus have a weak sensitivity when the key fob is not in direct proximity to the base station. To make key fobs more useful in security applications, such as in passive keyless entry systems for automobiles, it is therefore desirable to increase the sensitivity of these devices and thus their range of operation.

The simple solution to the problem would be to increase the size of the coil being used in the key fob. A larger coil will allow more flux lines to pass through it and thus have an increased sensitivity to the magnetic field in which it is placed. Indeed, this is the solution presented in U.S. Pat. No. 5,084,699, which employs a dual-coil magnet. A secondary coil is placed over the primary coil. The problem with this solution, and any other solution involving a coil of increased size is that it takes up more space, which is undesirable for key fob applications. It is necessary to maintain key fobs as small as possible so that they are not cumbersome for users. Therefore, any solution, which involves increasing the size of the key fob is undesirable. Furthermore, because this solution involves creating a larger coil, it therefore would have increased cost, which is also undesirable for obvious reasons.

Another solution, which seeks to increase the sensitivity of magnetic sensors is disclosed in U.S. Pat. No. 5,483,161. This solution is directed to a Faraday effect transducer, which employs a pair of flux concentrators mounted concentrically around a magneto-optic material. Such devices, however, are used for the general measurement of uniform magnetic fields, and are generally not suitable for use in passive keyless entry systems because they are generally too expensive and consume too much power.

Therefore, there is a need for a magnetic sensor, which is cost effective, small enough to fit within a key fob, and which has increased sensitivity over prior art sensors so that the range of operation for passive keyless entry systems is increased.

### SUMMARY OF THE INVENTION

The present invention overcomes the above-identified problems as well as other shortcomings and deficiencies of existing technologies by providing an apparatus and method for increasing the sensitivity of magnetic sensors. The apparatus is cost effective, small in size, and well suited for incorporation into key fobs used in passive keyless entry systems.

In one embodiment of the present invention, the apparatus for increasing the sensitivity of a magnetic sensor is provided. In this embodiment, the magnetic sensor includes a magnetic core, which is preferably rectangular or cylindrically shaped, and has a proximal end and a distal end. The sensor also includes a conductive wire wrapped around the magnetic core thereby forming a coil around the magnetic core. The sensor further includes a pair of magnetic flux concentrators magnetically coupled to the magnetic core, one at its proximal end and the other at its distal end. The magnetic flux concentrators are preferably oriented parallel to each other and perpendicular to the magnetic core. They are also preferably integrally formed with the magnetic core with the resulting structure being substantially dumbbell shaped.

In another embodiment of the present invention, an inductively coupled magnetic field transmission and detection system, which incorporates the apparatus for increasing the sensitivity of the magnetic sensor, is provided. The transmission and detection system includes a base station or transmitter having an inductor that generates a time varying magnetic field and a transponder or receiver inductively coupled to the transmitter, which has a magnetic sensor that senses the presence of the magnetic field. The magnetic sensor preferably includes the components identified above, namely, a magnetic core having a proximal end and a distal end; a conductive wire wrapped around the magnetic core thereby forming a coil around said magnetic core; and a pair of magnetic flux concentrators magnetically coupled to the magnetic core member at its proximal and distal ends.

In one implementation of the system embodiment, the receiver has modulation circuitry for sending a radio frequency (RF) signal back to the transmitter in response to detection of the magnetic field by the sensor. In this implementation, the transmitter further includes detection circuitry for detecting the RF signal being sent to it by the receiver.

In another implementation of the system embodiment, the receiver modulates the coil, which operates to create a characteristic change in the magnetic field generated by the inductor in the transmitter. This change in the magnetic field load can be observed by the coil in the transmitter. Data is thus modulated by the receiver by changing the loading of the transmitter drive coil.

In yet another embodiment of the present invention, a method of increasing the sensitivity of a magnetic sensor is provided. The method includes the steps of magnetically coupling a pair of magnetic flux concentrators to opposite ends of a magnetic core. In a preferred implementation of this embodiment, the magnetic flux concentrators are physically coupled to the magnetic core, and more preferably integrally formed with the magnetic core. In another preferred implementation of this embodiment, the magnetic flux concentrators are oriented parallel to each other and perpendicular to the magnetic core.

The primary advantage of the present invention is that the magnetic flux concentrators effectively force a larger window of magnetic flux through the coil and thus increase the sensitivity of the magnetic sensor. This is illustrated by a comparison of FIG. 1, which illustrates the flow of magnetic flux lines passing through a sensor without the magnetic flux concentrators, to FIG. 4, which illustrates the flow of magnetic flux lines passing through a sensor with the magnetic flux concentrators. This has the advantage of increasing the operating range of key fobs incorporating such magnetic sensors, which are used in passive keyless entry systems.

### BRIEF DESCRIPTION OF THE DRAWINGS

A more complete understanding of the present disclosure and advantages thereof may be acquired by referring to the following description taken in conjunction with the accompanying drawings wherein:

FIG. 1 is a block diagram of an inductively coupled magnetic field transmission and detection system according to the present invention.

FIG. 2 is a schematic diagram illustrating the flow of magnetic flux lines into a prior art magnetic sensor coil.

FIG. 3 is a schematic diagram of a magnetic sensor, which has increased sensitivity to a magnetic field, according to the present invention.

FIG. 4 is a schematic diagram illustrating the flow of magnetic flux lines into the magnetic sensor coil shown in FIG. 3.

### DETAILED DESCRIPTION OF THE PREFERRED EMBODIMENTS

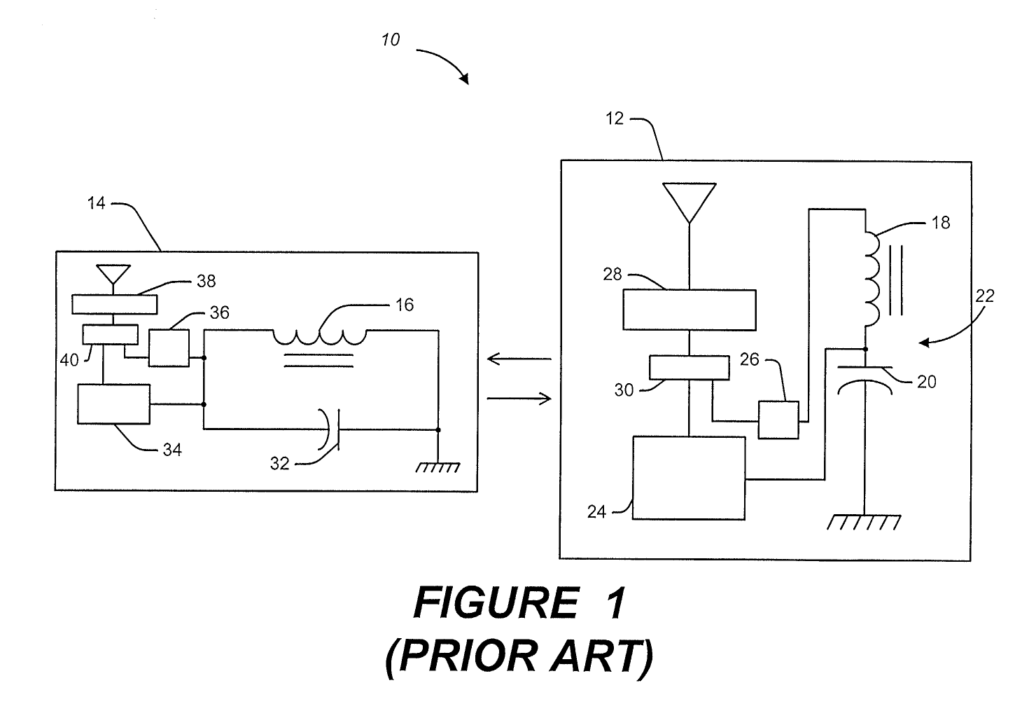

Referring now to the drawings, the details of preferred embodiments of the invention are schematically illustrated. FIG. 1 illustrates a block diagram of the basic elements of a prior art inductively coupled magnetic field transmission and detection system with reference numeral 10 referring generally to the system. The transmission and detection system 10 includes a base station or transmitter 12 and a receiver 14. Communication between the base station 12 and the receiver 14 occurs via magnetic coupling between a transponder coil 16 and a base station coil 18. The base station coil 18 is in series with a capacitor 20 to form a series resonant circuit 22, which alternatively could be a parallel circuit. The resonant circuit 22 is connected to an AM demodulator circuit 24 and a driver circuit 26. The AM demodulator circuit 24, the driver circuit 26 and a RF receiver 28 are all connected to a controller 30, as shown in FIG. 1. The base station 12 communicates with the receiver 14 by switching a 125 kHz (kilohertz) signal to the resonant circuit 22 on and off. Thus, the base station 12 magnetic field is switched on and off.

The transponder coil 16 is connected in parallel with a capacitor 32. The capacitor 32 and inductor 16 values are chosen to resonate at 125 kHz. However, as those of ordinary skill in the art will appreciate, other carrier frequencies are possible by changing the capacitor 32 or inductor 16 values. The transponder coil 16 forms the sensing element (magnetic sensor) in the receiver 14. The transponder coil 16 is connected to a receiver circuit 34 and a driver circuit 36. The receiver circuit 34, the driver circuit 36 and a RF transmitter 38 are all connected to a controller 40.

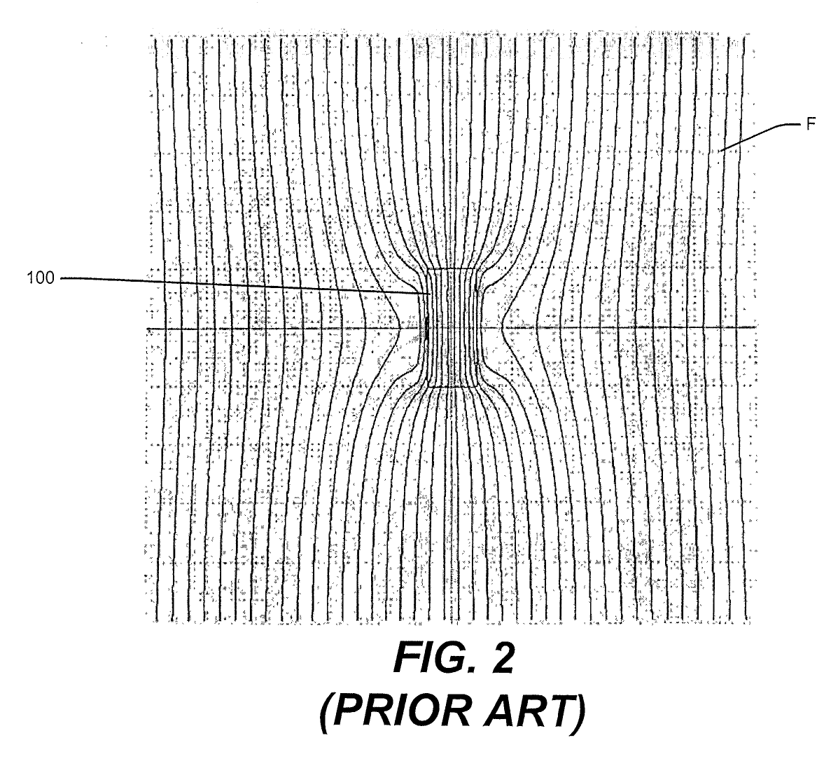

When the receiver 14 is brought into the base station 12 magnetic field, it magnetically couples with this field and draws energy from it. This phenomenon is illustrated in FIG. 2, which illustrates the flux lines of the magnetic field F being drawn into a prior art transponder coil 100. This loading effect can be observed as a change in voltage across the base station resonating capacitor 20. The receiver 14 communicates with the base station 12 by “shorting out” its parallel LC circuit using driver 36. This detunes the receiver 14 and removes the load, which is observed as a change in voltage across the base station resonating capacitor 20. The base station 12 capacitor voltage is the input to the base station AM demodulator circuit 24. The demodulator 24 extracts the transponder data for further processing by base station software (not shown).

Alternatively, the receiver 14 can communicate with the base station 12 by transmitting an RF signal through the RF transmitter 38. This signal can then be received by the base station 12 using its RF receiver 28. The demodulator 24 extracts the transponder data for further processing by base station software (not shown).

Further description of a transmission and detection system in which the present invention may be used can be found in the data sheets for the HCS473 transponder manufactured by Microchip Technologies, Inc., which are incorporated by reference herein. This data sheet can be found on Microchip's web site, which is www.microchip.com.

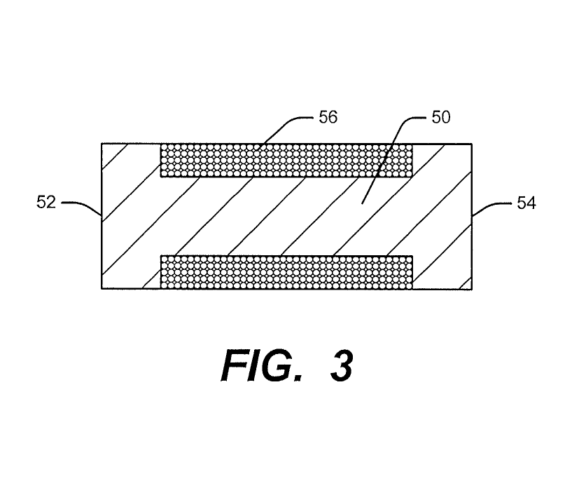

Turning to FIG. 3, the preferred embodiment of the magnetic sensor 16 according to the present invention is illustrated. At the heart of the sensor 16 is a magnetic core 50, which is preferably formed of ferromagnetic material, preferably ferrite. The magnetic core 50 may assume any shape, although it is preferably cylindrical or rectangular in shape. The magnetic core 50 has a proximal end and a distal end. A pair of magnetic flux concentrators 52 and 54 are magnetically coupled to the proximal and distal ends, respectively, of the magnetic core 50. The magnetic flux concentrators 52 and 54 are preferably formed of a ferromagnetic material, preferably ferrite. They also may assume any shape although are preferably cylindrical or disk-shaped or rectangular in shape. The magnetic flux concentrators 52 and 54 are preferably physically coupled to the magnetic core 50 and more preferably integrally formed therewith. In the most preferred embodiment, the magnetic core 50 and pair of magnetic flux concentrators 52 and 54 are formed in the shape of a dumbbell with both magnetic flux concentrators 52 and 54 being identical in size.

A conductive wire 56 is helically wound around the magnetic core 50, thereby making the sensor 16 an inductor, which can be used in a resonant circuit.

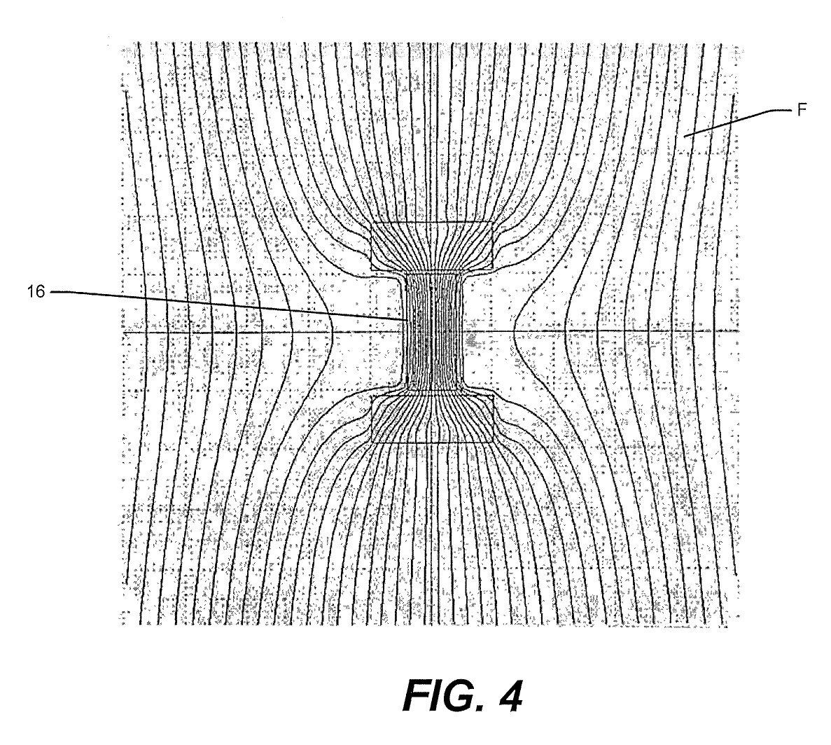

FIG. 4 illustrates the flow of magnetic flux lines F through the magnetic sensor 16 according to the present invention. As can be seen, the number of flux lines F passing through the magnetic sensor 16 is noticeably greater than the number of flux lines passing through the prior art sensor illustrated in FIG. 2. The pair of magnetic flux concentrators 52 and 54 draw more flux lines F into the sensor because they increase the magnet's surface area in the magnetic field. While it is mentioned above that the magnetic flux concentrators 52 and 54 can assume any shape, they only improve the sensitivity of existing sensors if they are configured to occupy a greater area normal to the flux lines of the magnetic field then was occupied by prior sensors. In this regard, it was determined that the dumbbell configuration is the most preferred embodiment, because it permits a maximum surface area exposure of the flux concentrators to the magnetic field, without increasing the size of the sensor. It is desired that one embodiment of the magnetic sensor 16 fit within a space of approximately 10 mm by 5 mm by 3 mm, which is the space currently occupied by the transponder coil of a Microchip HCS473 transponder. The configuration of the device shown in FIG. 3 satisfies these constraints. However, it should be recognized by those of ordinary skill in the art that the magnetic sensor 16 can be sized to meet the requirements of any system.

The table below illustrates how the present invention improves the sensitivity of magnetic sensors used in transponders. Column A illustrates the range possible using an existing 4308TC715RFID transponder coil manufactured by Coilcraft with a Microchip HCS403 transponder. Column B illustrates the results for the same coil with the addition of a pair of magnetic flux concentrators. The results were obtained using the same HCS 403 device and setup at 6 V (volts) at room temperature. The results show an average increase on the order of fifty percent (50%).

| AXIS | A | B |
|---|---|---|
| X-Axis Input Range | 42.25″ | 60.25″ |
| Y-Axis Input Range | 54.25″ | 85.5″ |
| Z-Axis Input Range | 62.5″ | 92″ |

The invention, therefore, is well adapted to carry out the objects and attain the ends and advantages mentioned, as well as others inherent therein. While the invention has been depicted, described, and is defined by reference to particular preferred embodiments of the invention, such references do not imply a limitation on the invention, and no such limitation is to be inferred. The invention is capable of considerable modification, alteration, a equivalents in form and function, as will occur to those of ordinary skill in the art. The depicted and described preferred embodiments of the invention are exemplary only, and are not exhaustive of the scope of the invention. Consequently, the invention is intended to be limited only by the spirit and scope of the appended claims, giving full cognizance to equivalents in all respects.

What is claimed:

1. A magnetic sensor for use an inductively coupled magnetic field transmission and detection system comprising:
(a) a magnetic core having a proximal end and a distal end;
(b) a conductive wire wrapped around said magnetic core thereby forming a coil around said magnetic core;
(c) a first magnetic flux concentrator magnetically coupled to the magnetic core at its proximal end; and
(d) a second magnetic flux concentrator magnetically coupled to the magnetic core at its distal end.

2. A magnetic sensor according to claim 1, wherein the first magnetic flux concentrator is aligned substantially parallel to the second magnetic flux concentrator.

3. A magnetic sensor according to claim 2, wherein the first magnetic flux concentrator and the second magnetic flux concentrator are aligned substantially perpendicular to the magnetic core.

4. A magnetic sensor according to claim 1, wherein the first magnetic flux concentrator and the second magnetic flux concentrator are integrally formed with the magnetic core.

5. A magnetic sensor according to claim 4, wherein the first flux magnetic concentrator, the second magnetic flux concentrator, and the magnetic core form a structure, which is substantially dumbbell shaped.

6. A magnetic sensor according to claim 1, wherein the magnetic core is substantially cylindrical in shape and the conductive wire is helically wound around said magnetic core.

7. A magnetic sensor according to claim 6, wherein the first and second magnetic flux concentrators are substantially disk shaped structures having substantially equal diameters.

8. A magnetic sensor according to claim 1, wherein the magnetic core and first and second magnetic flux concentrators are substantially rectangular in shape.

9. A magnetic sensor according to claim 1, wherein the magnetic core and first and second magnetic flux concentrators comprise a ferromagnetic material.

10. An inductively coupled magnetic field transmission and detection system comprising:
(a) a transmitter having an inductor that generates a time varying magnetic field; and
(b) a receiver inductively coupled to the transmitter, which has a magnetic sensor that senses the presence of the magnetic field, said magnetic sensor comprising:
(i) a magnetic core having a proximal end and a distal end;
(ii) a conductive wire wrapped around said magnetic core thereby forming a coil around said magnetic core;
(iii) a first magnetic flux concentrator magnetically coupled to the magnetic core member at its proximal end; and
(iv) a second magnetic flux concentrator magnetically coupled to the magnetic core at its distal end.

11. An inductively coupled magnetic field transmission and detection system according to claim 10, wherein the first magnetic flux concentrator is aligned substantially parallel to the second magnetic flux concentrator.

12. An inductively coupled magnetic field transmission and detection system according to claim 11, wherein the first magnetic flux concentrator and the second magnetic flux concentrator are aligned substantially perpendicular to the magnetic core.

13. An inductively coupled magnetic field transmission and detection system according to claim 12, wherein the first magnetic flux concentrator and the second magnetic flux concentrator are integrally formed with the magnetic core.

14. An inductively coupled magnetic field transmission and detection system according to claim 13, wherein the first magnetic flux concentrator, the second magnetic flux concentrator, and the magnetic core form a structure, which is substantially dumbbell shaped.

15. An inductively coupled magnetic field transmission and detection system according to claim 10, wherein the magnetic core is substantially cylindrical in shape and the conductive wire is helically wound around the magnetic core.

16. An inductively coupled magnetic field transmission and detection system according to claim 15, wherein the first and second magnetic flux concentrators are substantially disk shaped structures having substantially equal diameters.

17. An inductively coupled magnetic field transmission and detection system according to claim 10, wherein the magnetic core and first and second magnetic flux concentrators are substantially rectangular in shape.

18. An inductively coupled magnetic field transmission and detection system according to claim 10, wherein the magnetic core and first and second magnetic flux concentrators comprise a ferromagnetic material.

19. An inductively coupled magnetic field transmission and detection system according to claim 10, wherein the transmitter further comprises a capacitor connected in series with the inductor to form a series resonant circuit.

20. An inductively coupled magnetic field transmission and detection system according to claim 19, wherein the transmitter further comprises an AM demodulator circuit and a driver circuit connected to the resonant circuit.

21. An inductively coupled magnetic field transmission and detection system according to claim 20, wherein the transmitter further comprises a controller connected to the AM demodulator circuit, the driver circuit, and a RF receiver.

22. An inductively coupled magnetic field transmission and detection system according to claim 10, wherein the receiver further comprises a capacitor connected in parallel with the magnetic sensor.

23. An inductively coupled magnetic field transmission and detection system according to claim 22, wherein the receiver further comprises a receiver circuit and a driver circuit connected to the capacitor and magnetic sensor.

24. An inductively coupled magnetic field transmission and detection system according to claim 23, wherein the receiver further comprises a controller connected to the receiver circuit, the driver circuit, and a RF transmitter.

25. A method of increasing the sensitivity of a magnetic sensor having a magnetic core, which has a proximal end and a distal end, comprising the steps of:
(a) magnetically coupling a first magnetic concentrator to the proximal end of the magnetic core; and
(b) magnetically coupling a second magnetic concentrator to the distal end of the magnetic core.

26. A method of increasing the sensitivity of a magnetic sensor according to claim 25, further comprising the step of orienting the first magnetic concentrator and the second magnetic concentrator parallel to one another.

27. A method of increasing the sensitivity of a magnetic sensor according to claim 26, further comprising the step of orienting the first magnetic concentrator and the second magnetic concentrator perpendicular to the magnetic core.

28. A method of increasing the sensitivity of a magnetic sensor according to claim 27, further comprising the steps of physically coupling the first magnetic concentrator to the proximal end of the magnetic core and the second magnetic concentrator to the distal end of the magnetic core.

29. A method of increasing the sensitivity of a magnetic sensor according to claim 25, further comprising the step of integrally forming the first and second magnetic concentrators with the magnetic core.
